(19) United States
(12) Patent Application Publication
(10) Pub. No.: US 2026/0238171 A1
(43) Pub. Date: Aug. 13, 2026

(54) SC INTEGRATOR

(71) Applicant: Robert Bosch GmbH, Stuttgart (DE)

(72) Inventors: Steffen Becker, Coswig (DE); Amin Jemili, Kusterdingen (DE)

(21) Appl. No.: 19/450,234

(22) Filed: Jan. 15, 2026

(30) Foreign Application Priority Data
Jan. 30, 2025 (DE) 10 2025 103 343.9

(51) Int. Cl. H03F 3/45

(52) U.S. Cl. CPC H03F 3/45475

(57) ABSTRACT

A switched-capacitor (SC) integrator. The SC integrator includes: a first operational amplifier including an inverting input, a non-inverting input, and an output; a second operational amplifier including an inverting input, a non-inverting input, and an output; a first capacitor configured to sample an input signal; a second capacitor configured to store an offset voltage; a third capacitor configured to store an offset voltage; an integrating capacitor which is connected between the output of the first operational amplifier and the inverting input of the first operational amplifier; a first switch which connects the first capacitor selectively to the input signal or ground; and a second switch which connects the third capacitor selectively to the inverting input of the second operational amplifier or ground.

### FIELD

The disclosure relates to an SC integrator.

### BACKGROUND INFORMATION

The present disclosure relates to an SC integrator having the transfer function H(z)=z⁻¹/(1-z⁻¹), the SC integrator being used in a circuit having additional requirements for temporal behavior.

Switched-capacitor (SC) circuits have long been established and are widely used in analog signal processing, in particular in integrated circuits. Their advantage is the good feasibility of precise circuits which have low area requirements and are easy to integrate into CMOS processes. The basic operation is based on the discrete storing of charge on capacitors and the redistribution of the charge by means of switches. Various analog functions such as filters, amplifiers, and integrators can thus be implemented.

SC integrators are an elementary part of many SC circuits. The transfer function H(z)=z⁻¹/(1-z⁻¹) corresponds to an ideal delay element followed by an ideal accumulator in the discrete-time domain. This function is generally conventional and is used in various applications.

The related art includes various implementations of SC integrators having this transfer function or similar transfer functions. There are simple circuits having few switches and capacitors, which approximate the desired transfer function.

These circuits are often susceptible to parasitic capacitances and clock feedthrough. There are circuits having reduced sensitivity to parasitic effects and improved linearity. For this purpose, techniques such as fully differential circuits or special switch arrangements are employed, for example. Furthermore, SC integrators have applications in areas such as A/D converters, D/A converters, filters, and control loops. The requirements for the integrator may vary depending on the application, for example in terms of accuracy, speed, or power consumption.

FIG. 1 shows an inverting switched-capacitor integrator. It comprises two capacitors Ci, Caz, two switches p1, p2, and one operational amplifier. Vin is the input, and Vout is the output. Cint is the integrating capacitor.

There are some disadvantages of this traditional implementation.

Switching the capacitors by means of the switches p1 and p2 couples charge into the integrating capacitor Cint. This leads to undesirable disturbances at the output Vout which are proportional to the clock frequency and the amplitude of the clock signals.

In real circuits, parasitic capacitances occur, for example between the switch terminals and ground or between the capacitor plates and the substrate. These parasitic capacitances influence the accuracy of integration and can lead to undesired signal paths.

The operational amplifier is not ideal and has non-linearities such as offset voltage, finite amplification, and slew rate limits. These non-linearities influence the accuracy and dynamic behavior of the integrator.

The switches have a finite resistance in the switched-on state (ON resistance). This resistance influences the charging and discharging times of the capacitors and can lead to inaccuracies, in particular at high frequencies.

The dynamic range of the integrator is limited by the supply voltage of the operational amplifier and the capacitance values. Large input voltages may result in saturation of the operational amplifier.

These disadvantages of the related art may negatively influence the performance of the integrator and may limit the use in circuits having high requirements for temporal behavior.

### SUMMARY

The present disclosure aims to overcome these disadvantages and to provide an improved SC integrator having optimized temporal behavior.

### BRIEF DESCRIPTION OF THE DRAWINGS

FIG. 1 shows a switched-capacitor integrator according to the related art in a schematic illustration.

FIG. 2 shows a circuit, according to an example embodiment of the present disclosure, of a switched capacitor integrator in a schematic illustration,

FIG. 3 shows a further circuit, according to an example embodiment of the present disclosure, of a switched capacitor integrator in a schematic illustration,

FIG. 4 shows the operation of the circuit of the present disclosure in a schematic illustration.

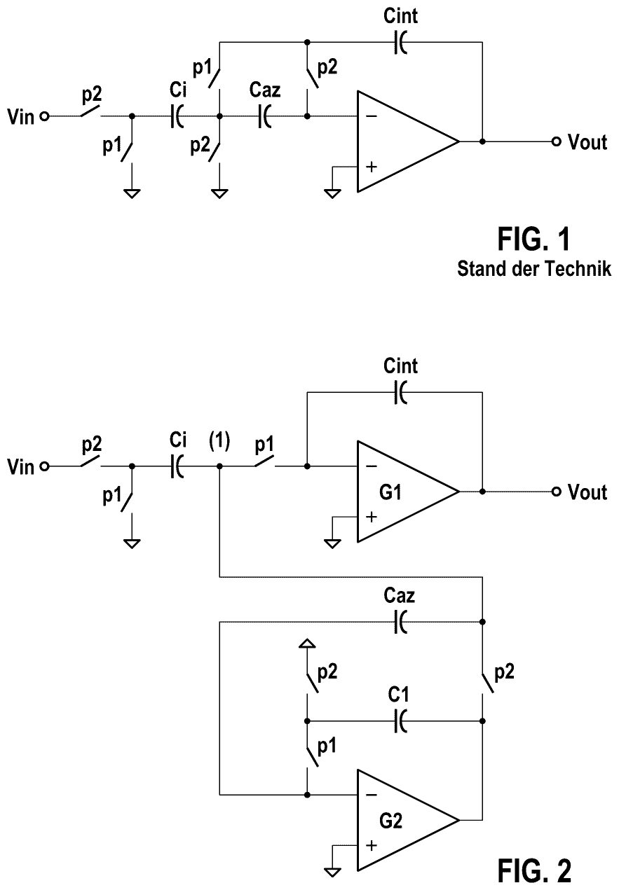

### DETAILED DESCRIPTION OF EXAMPLE EMBODIMENTS

FIG. 2 shows a circuit, according to the present disclosure, of a switched-capacitor integrator having two operational amplifiers G1, G2 and multiple switches p1, p2. It differs from the circuit in the related art by the addition of a second operational amplifier G2 and the capacitor C1.

The circuit operates in two phases. In phase P1, the input Vin is connected to the inverting input of G1 via the capacitor Ci. At the same time, the capacitor Caz is connected to the output of G2 via the switch p1. The second operational amplifier G2 controls its output such that its inverting input is virtually at ground potential. Thus, the offset of G2 is transferred to the inverting input of G1 via C1 and Caz. G1 integrates the difference between Vin and the offset of G2. The result is stored in Cint and is present at the output Vout.

In phase P2, Ci is disconnected from Vin and grounded. At the same time, Caz is disconnected from the output of G2 and likewise grounded. The capacitor C1 is then connected to ground via the switch p2. In this phase, G2 amplifies its own offset. Cint retains the charge from the previous phase, so that Vout holds the integrated value from phase p1.

As mentioned, the structure according to the present disclosure is free of the offset of the amplifier in Vout both during phase P1 and during phase P2. This is achieved by means of the second operational amplifier G2 and the capacitor C1. In phase p1, the offset of G2 is transferred to the input of G1 and thus deducted from the integration. In phase P2, the input of G1 is grounded, and therefore the offset of G1 plays no role. The output Vout retains the value from phase P1, from which the offset of G2 has already been removed. Although the offset of G2 is amplified in phase P2, it does not influence the output Vout, since Caz is grounded in this phase.

Because of the advantageous circuit topology and the use of a second operational amplifier, the influence of the offset voltages of both operational amplifiers on the output Vout is minimized. This results in higher accuracy and improved temporal behavior of the integrator in comparison with traditional SC integrators.

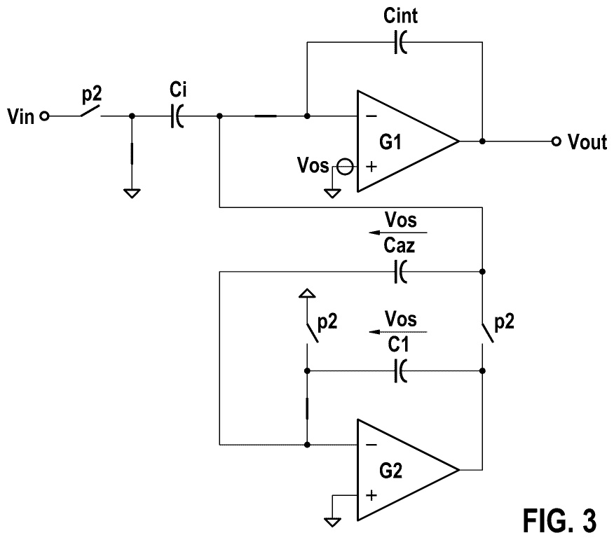

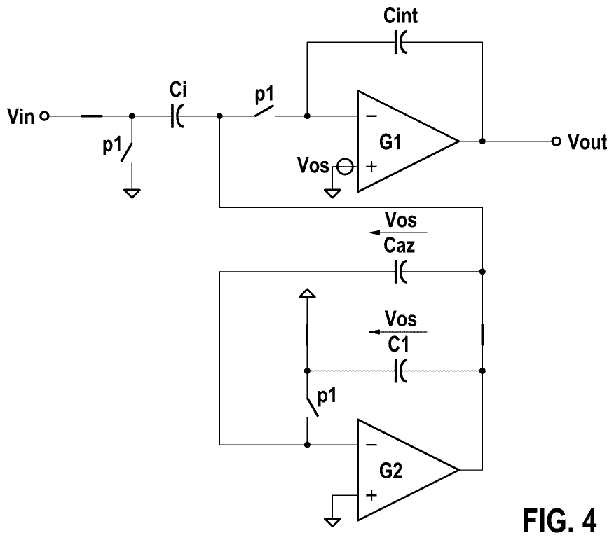

FIG. 3 shows a circuit corresponding to the circuit of FIG. 2, but with explicit labeling of the offset voltages Vos of the operational amplifiers G1 and G2.

The circuit operates in two phases. In phase P1, the switch p1 is closed and p2 is opened. Vin is connected to the inverting input of G1 via Ci. At the same time, the inverting input of G2 is connected to ground via C1.

The offset of G1 Vos_G1 appears at the inverting input of G1 and is added to the input signal of Vin. Since the operational amplifier G1 is assumed to be an ideal amplifier having infinite amplification, the voltage at its inverting input must be equal to the voltage at its non-inverting input (virtual short circuit). Since the non-inverting input of G1 is grounded, the inverting input, i.e. the node 1, is also virtually at ground potential.

The offset of G1 is then stored by means of the capacitor Caz and the capacitor C1. Caz is charged to the voltage Vos_G1, and since the node between Caz and C1 is virtually at ground, C1 also charges to the voltage Vos_G1 (with reverse polarity). This simultaneous storing of the offset on both capacitors is crucial for later compensation.

In phase P1, the offset of G1 at the node 1 is effectively and simultaneously stored on the capacitors Caz and C1. This charge storage is the basis for the offset compensation in the following phase P2. The offset of G2 does not play a role in this phase, because the inverting input of G2 is at ground potential.

FIG. 4 shows the operation of the circuit in phase P2, in which the offset compensation takes place.

In phase P2, switch p2 is closed and p1 is open. Ci is now disconnected from Vin and connected to ground. The inverting input of G2 is connected to the node 1 via C1, and Caz is still connected to the node 1.

The crucial point is that in this phase G2 does not generate its virtual ground point at the node 1, but rather a value shifted by the voltage stored on Caz in phase p1. This voltage corresponds exactly to the offset of G1 (Vos_G1) minus the offset of G2 (Vos_G2). The node 1 is thus at the potential Vgnd+Vos_G1−Vos_G2.

Since the node 1 is then at the potential Vgnd+Vos_G1−Vos_G2, Ci is charged in this phase to the voltage Vgnd-Vos_G1+Vos_G2. The charge integrated on Cint results from the difference of the charges on Ci in phase P1 and phase P2:

$$Q 1 = ( V in - V os \_ G 1 ) * Ci \qquad Phase P1$$

$$Q 2 = ( V gnd - V os \_ G 1 + V os \_ G 2 ) * Ci \qquad Phase P2$$

Integrated charge: Qinteg=Q1−Q2=(Vin-Vgnd-Vos_G2)*Ci

The integrated charge is thus ideally free of the offset of G1, but is still influenced by the offset of G2.

As mentioned in the description, the circuit also compensates the amplification error of G1. The amplification error is expressed as an additional offset voltage at the input of G1, said offset voltage being proportional to the output signal. However, this offset voltage is compensated by the same mechanism as the actual offset of G1.

It is pointed out that the offset of G2 is likewise stored on Caz. The voltage on Caz results from the superposition of the offset voltages of G1 and G2: V(Caz)=Vos_G1−Vos_G2. This explains why the integrated charge is still dependent on the offset of G2.

In phase P2, the circuit compensates the offset of G1 and the amplification error of G1. The offset of G2 is also taken into account, but not fully compensated. The remaining dependence on the offset of G2 could be another point of optimization for the circuit.

1-10. (canceled)

11. A switched-capacitor integrator, comprising:
a first operational amplifier including an inverting input, a non-inverting input, and an output;
a second operational amplifier including an inverting input, a non-inverting input, and an output;
a first capacitor configured to sample an input signal;
a second capacitor configured to store an offset voltage;
a third capacitor configured to store an offset voltage;
an integrating capacitor which is connected between the output of the first operational amplifier and the inverting input of the first operational amplifier;
a first switch which connects the first capacitor selectively to the input signal or ground;
a second switch which connects the third capacitor selectively to the inverting input of the second operational amplifier or ground;
wherein the second capacitor is connected between the output of the second operational amplifier and the inverting input of the first operational amplifier in a first phase and is connected to ground in a second phase;
wherein in the first phase, an offset of the first operational amplifier is stored onto the second capacitor and the third capacitor;
wherein in the second phase, the second operational amplifier generates a virtual ground potential which is shifted by the offset of the first operational amplifier stored on the second capacitor, and, as a result, the offset of the first operational amplifier is compensated.

12. The switched-capacitor integrator according to claim 11, wherein an offset of the second operational amplifier is stored on the second capacitor.

13. The switched-capacitor integrator according to claim 11, wherein an amplification error of the first operational amplifier is compensated by the switched-capacitor integrator.

14. The switched-capacitor integrator according to claim 11, wherein the switched-capacitor integrator is implemented using integrated circuit technology.

15. A method for integrating an input signal using a switched-capacitor integrator, the switched-capacitor integrator including:
a first operational amplifier including an inverting input, a non-inverting input, and an output,
a second operational amplifier including an inverting input, a non-inverting input, and an output,
a first capacitor configured to sample an input signal,
a second capacitor configured to store an offset voltage,
a third capacitor configured to store an offset voltage,
an integrating capacitor which is connected between the output of the first operational amplifier and the inverting input of the first operational amplifier,
a first switch which connects the first capacitor selectively to the input signal or ground,
a second switch which connects the third capacitor selectively to the inverting input of the second operational amplifier or ground,
wherein the second capacitor is connected between the output of the second operational amplifier and the inverting input of the first operational amplifier in a first phase and is connected to ground in a second phase,
wherein in the first phase, an offset of the first operational amplifier is stored onto the second capacitor and the third capacitor,
wherein in the second phase, the second operational amplifier generates a virtual ground potential which is shifted by the offset of the first operational amplifier stored on the second capacitor, and, as a result, the offset of the first operational amplifier is compensated,
the method comprising the following steps:
a) charging the first capacitor with a difference between the input signal and the offset of the first operational amplifier in the first phase;
b) storing the offset of the first operational amplifier on the second capacitor and the third capacitor in the first phase;
c) generating a virtual ground potential at the inverting input of the first operational amplifier in the second phase, the virtual ground potential being shifted by the offset of the first operational amplifier stored on the second capacitor;
d) integrating a difference between a charge on the first capacitor in the first phase and a charge on the first capacitor in the second phase on the integrating capacitor.

16. A method for integrating an input signal using a switched-capacitor integrator, comprising the following steps:
a) providing a switched-capacitor integrator including a first operational amplifier, a second operational amplifier, a first capacitor, a second capacitor, a third capacitor, and an integrating capacitor;
b) connecting the first capacitor to the input signal in a first phase;
c) connecting the second capacitor to an output of the second operational amplifier and an inverting input of the first operational amplifier in the first phase;
d) grounding an inverting input of the second operational amplifier using the third capacitor, in the first phase;
e) disconnecting the first capacitor from the input signal and grounding the first capacitor in a second phase;
f) grounding the second capacitor in the second phase;
g) connecting the third capacitor to ground in the second phase;
h) integrating difference of charges on the first capacitor between the first phase and the second phase on the integrating capacitor.

17. The method according to claim 16, wherein an offset of the first operational amplifier is stored on the second capacitor and the third capacitor in the first phase.

18. The method according to claim 16, wherein an offset of the second operational amplifier is stored on the second capacitor.

19. The method according to claim 16, wherein an amplification error of the first operational amplifier is compensated.

20. The method according to claim 16, wherein the method is performed in an integrated circuit.
